(19) United States
(12) Patent Application Publication
(10) Pub. No.: US 2020/0359514 A1
(43) Pub. Date: Nov. 12, 2020

(54) FOLDABLE ELECTRONIC DEVICE

(71) Applicants: Che-Hsien Lin, Taipei City (TW); Che-Hsien Chu, Taipei City (TW); Ko-Yen Lu, Taipei City (TW)

(72) Inventors: Che-Hsien Lin, Taipei City (TW); Che-Hsien Chu, Taipei City (TW); Ko-Yen Lu, Taipei City (TW)

(73) Assignee: COMPAL ELECTRONICS, INC., Taipei City (TW)

(21) Appl. No.: 16/866,511

(22) Filed: May 4, 2020

Related U.S. Application Data
(60) Provisional application No. 62/844,139, filed on May 7, 2019.

(51) Int. Cl. H05K 5/02; H05K 5/00; E05D 3/18; E05D 3/12; E05D 11/00; F16H 21/54

(52) U.S. Cl. CPC H05K 5/0226; H05K 5/0017; E05D 3/18; E05Y 2201/11; E05D 11/0054; F16H 21/54; E05Y 2900/606; E05D 3/12

(57) ABSTRACT

A foldable electronic device including a first body, a hinge module, a second body, a second body, a first shielding element, a second shielding element and a linkage mechanism is provided. The hinge module is pivotally connected to the first body. The second body is pivotally connected to the hinge module. The first shielding element is slidably disposed on the first body. The second shielding element is slidably disposed on the second body. The linkage mechanism is disposed on the first body, the first shielding element, the second body and the second shielding element. The linkage mechanism is changeable between first and second states to drive the first and second elements to slide. In the first state, the first and second shielding elements expose a first area. In the second state, the first and second shielding elements expose a second area. The first area is larger than the second area.

### CROSS-REFERENCE TO RELATED APPLICATION

This application claims the priority benefit of U.S. provisional application No. 62/844,139, filed on May 7, 2019. The entirety of the above-mentioned patent application is hereby incorporated by reference herein and made a part of this specification.

### TECHNICAL FIELD

The invention relates to a foldable electronic device, and more particularly, to a foldable electronic device capable of covering a gap between first body and second body.

### BACKGROUND

In general, a foldable electronic device that can be unfolded to a large angle includes a first body, a second body, a hinge module, and a cover. The second body is rotatably disposed on the first body through the hinge module, and the cover is further used to cover the hinge module. However, to allow the first body and the second body to be unfolded to the large angle, a gap must be preserved between the cover and the first body and between the cover and the second body to avoid structural interferences between the cover and the first body and between the cover and the second body. Such gap will make the folding electronic device looks less attractive.

### SUMMARY

The invention provides a folding electronic device, which can solve the problem that the conventional folding electronic device looks less attractive.

A foldable electronic device of the invention includes a first body, a hinge module, a second body, a second body, a first shielding element, a second shielding element, and a linkage mechanism. The hinge module is pivotally connected to the first body. The second body is pivotally connected to the hinge module. The first shielding element is slidably disposed on the first body. The second shielding element is slidably disposed on the second body. The linkage mechanism is disposed on the first body, the first shielding element, the second body and the second shielding element. The linkage mechanism is changeable between a first state and a second state to drive the first shielding element and the second shielding element to slide. When the linkage mechanism is in the first state, the first shielding element and the second shielding element expose a first area. When the linkage mechanism is in the second state, the first shielding element and the second shielding element expose a second area. The first area is larger than the second area.

In an embodiment of the invention, when the linkage mechanism is in the first state, the second body is folded relative to the first body. When the linkage mechanism is in the second state, the second body is unfolded to a first angle relative to the first body.

In an embodiment of the invention, the linkage mechanism further includes a third state. When the linkage mechanism is in the third state, the second body is unfolded to a second angle relative to the first body. The first angle is greater than the second angle.

In an embodiment of the invention, the first angle includes 180 degrees. The second angle includes 65 degrees.

In an embodiment of the invention, the foldable electronic device further includes a cover. The cover is disposed on the linkage mechanism.

In an embodiment of the invention, the linkage mechanism includes a first active element, a first rotating element, a first linkage element, a first link rod and a fixing base. The first active element is fixed to the first shielding element. The first rotating element is rotatably disposed on the first body, and coupled to the first active element. The first linkage element is movably disposed on the first rotating element, and slidably disposed on the first active element. The first link rod is rotatably disposed on the first linkage element. The fixing base is fixed on the cover, and the first link rod is rotatably disposed on the fixing base.

In an embodiment of the invention, the first active element includes a first teeth portion. The first rotating element includes a second teeth portion coupled to the first teeth portion.

In an embodiment of the invention, the first active element includes a first groove. The first rotating element includes a second groove. The first linkage element includes a first shaft. The first shaft is inserted to the first groove and the second groove.

In an embodiment of the invention, the second groove includes a first portion and a second portion connecting the first portion. The first portion extends along a first direction. The second portion extends along a second direction. A third angle is included between the first direction and the second direction.

In an embodiment of the invention, the first shaft is capable of driving the first rotating element, the first active element and the first shielding element to move when the first shaft slides in the first portion. The first rotating element, the first active element and the first shielding element are stationary when the first shaft slides in the second portion.

In an embodiment of the invention, the linkage mechanism further includes a second active element, a second rotating element, a second linkage element and a second link rod. The second active element is fixed to the second shielding element. The second rotating element is rotatably disposed on the second body, and coupled to the second active element. The second linkage element is movably disposed on the second rotating element, and slidably disposed on the second active element. The second link rod is rotatably disposed on the linkage element, and the second link rod is rotatably disposed on the fixing base.

In an embodiment of the invention, the foldable electronic device further includes a flexible display screen. The flexible display screen is disposed on the first body and the second body.

Based on the above, the foldable electronic device of the invention can shield the internal components by the first shielding element, the second shielding element and the cover to achieve beautiful appearance.

To make the aforementioned more comprehensible, several embodiments accompanied with drawings are described in detail as follows.

### BRIEF DESCRIPTION OF THE DRAWINGS

FIG. 1 is a 3D view of a foldable electronic device in an embodiment of the invention.

FIG. 2 is a partially enlarged diagram of the foldable electronic device of FIG. 1 unfolded to a first angle from another perspective.

FIG. 3 is a 3D view of the linkage mechanism of the foldable electronic device of FIG. 1.

FIG. 4 is an explosion view of the linkage mechanism of the foldable electronic device of FIG. 1 with illustration of certain components omitted.

FIG. 5 is a partially enlarged diagram of the foldable electronic device of FIG. 1 from another perspective.

FIG. 6 is a partial cross-sectional view of the foldable electronic device of FIG. 5.

FIG. 7 is a top view of the foldable electronic device of FIG. 5 with illustration of certain components omitted.

FIG. 8 is a cross-sectional view of the foldable electronic device of FIG. 2.

FIG. 9 is a top view of the foldable electronic device of FIG. 2 with illustration of certain components omitted.

FIG. 10 is a partially enlarged diagram of the foldable electronic device of FIG. 1 unfolded to a second angle from another perspective.

FIG. 11 is a cross-sectional view of the foldable electronic device of FIG. 10.

FIG. 12 is a top view of the foldable electronic device of FIG. 10 with illustration of certain components omitted.

FIG. 13 and FIG. 14 are schematic views of a foldable electronic device in another embodiment of the invention.

### DETAILED DESCRIPTION

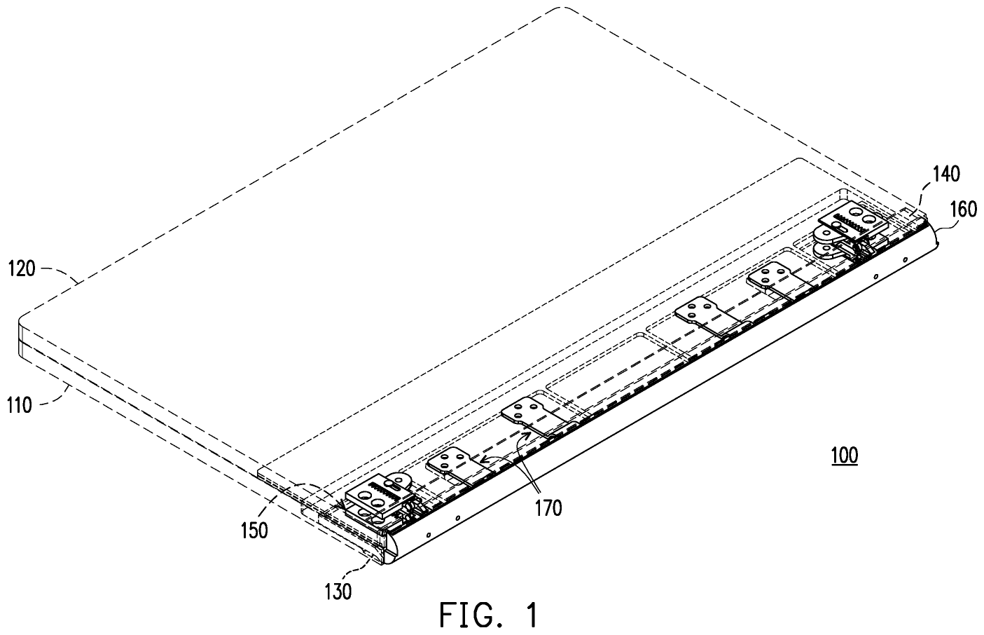

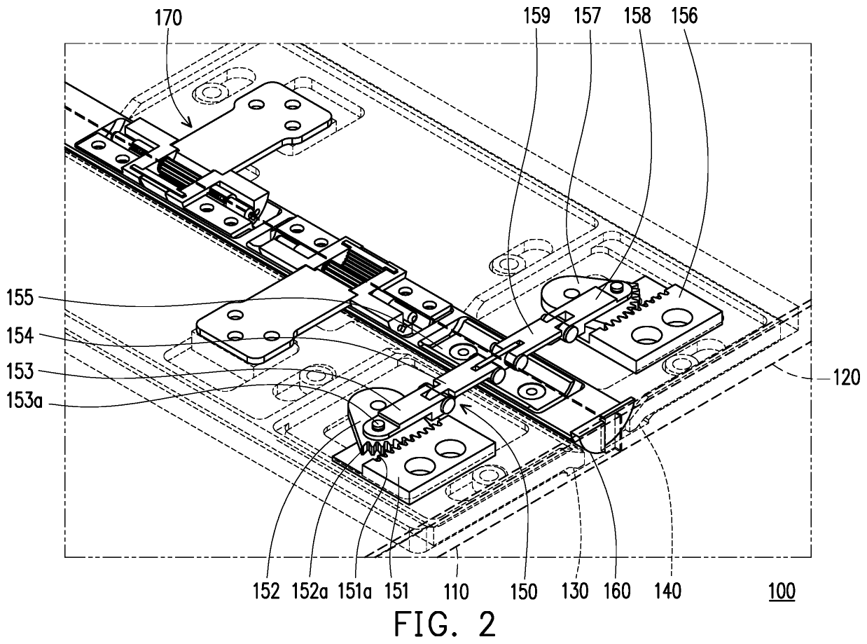

FIG. 1 is a 3D view of a foldable electronic device in an embodiment of the invention. FIG. 2 is a partially enlarged diagram of the foldable electronic device of FIG. 1 unfolded to a first angle from another perspective. For clarity and ease of explanation, certain structures are shown in broken lines in FIG. 1 and FIG. 2. Referring to FIG. 1 and FIG. 2, a foldable electronic device 100 of the present embodiment includes a first body 110, a second body 120, a hinge module 170, a first shielding element 130, a second shielding element 140 and a linkage mechanism 150. The hinge module 170 is pivotally connected to the first body 110. The second body 120 is pivotally connected to the hinge module 170. The first shielding element 130 is slidably disposed on the first body 110. The second shielding element 140 is slidably disposed on the second body 120. The linkage mechanism 150 is disposed on the first body 110, the first shielding element 130, the second body 120 and the second shielding element 140.

The linkage mechanism 150 of the present embodiment is changeable between a first state and a second state to drive the first shielding element 130 and the second shielding element 140 to slide. When the linkage mechanism 150 is in the first state, the first shielding element 130 and the second shielding element 140 expose a first area. When the linkage mechanism 150 is in the second state, the first shielding element 130 and the second shielding element 140 expose a second area. The first area is larger than the second area. In other words, when the linkage mechanism 150 is in the first state, the first shielding element 130 and the second shielding element 140 can shield a gap and an inner structure between the first body 110 and the second body 120 to help improving the appearance of the folding electronic device 100. In addition, in the process that the linkage mechanism 150 drives the first shielding element 130 and the second shielding element 140, the first shielding element 130 and the second shielding element 140 can shield the gap between the first body 110 and the second body 120 without interfering with other structures.

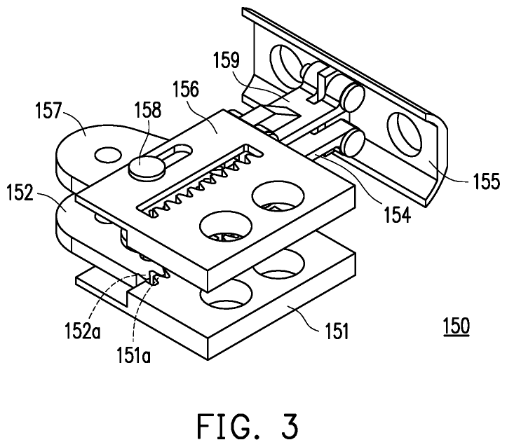

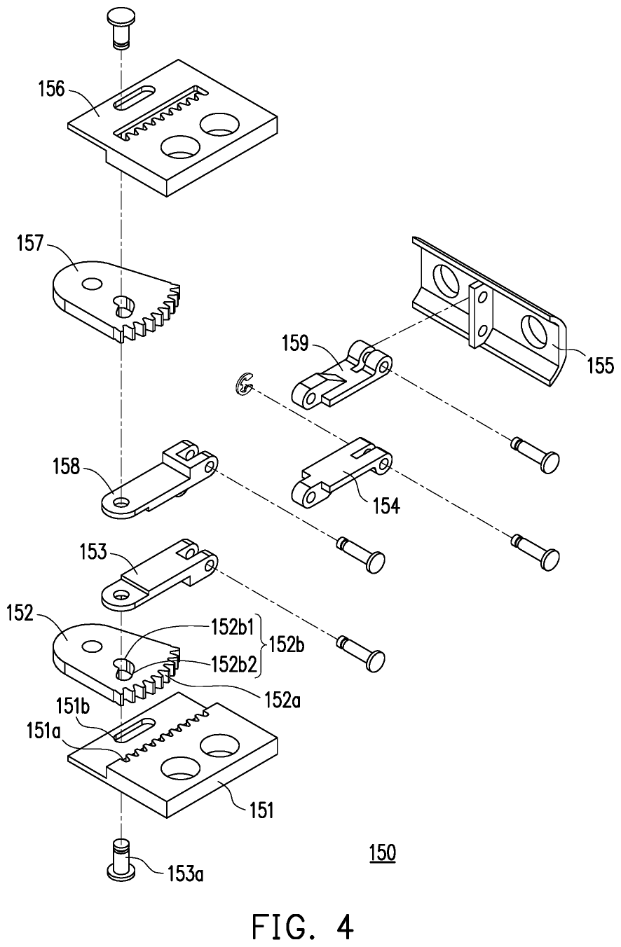

FIG. 3 is a 3D view of the linkage mechanism 150 of the foldable electronic device 100 of FIG. 1. FIG. 4 is an explosion view of the linkage mechanism of the foldable electronic device 100 of FIG. 1 with illustration of certain components omitted. For clarity and ease of explanation, certain structures are omitted in FIG. 4. Referring to FIG. 1, FIG. 2, FIG. 3 and FIG. 4, the linkage mechanism 150 of the present embodiment includes a first active element 151, a first rotating element 152, a first linkage element 153, a first link rod 154 and a fixing base 155. The first active element 151 is fixed to the first shielding element 130. The first rotating element 152 is rotatably disposed on the first body 110 through the hinge module 170, and the first rotating element 152 is coupled to the first active element 151. The first linkage element 153 is movably disposed on the first rotating element 152, and the first linkage element 153 is slidably disposed on the first active element 151. The first link rod 154 is rotatably disposed on the first linkage element 153. A cover 160 is disposed on the fixing base 155 of the linkage mechanism 150, and the first link rod 154 is rotatably disposed on the fixing base 155. In the process that the first body 110 is unfolded/folded relative to the second body 120, the cover 160 can shield the gap and the inner structure between the first body 110 and the second body 120 without interfering with other structures.

Similarly, the linkage mechanism 150 further includes a second active element 156, a second rotating element 157, a second linkage element 158 and a second link rod 159. The second active element 156 is fixed to the second shielding element 140. The second rotating element 157 is rotatably disposed on the second body 120, and the second rotating element 157 is coupled to the second active element 156. The second linkage element 158 is movably disposed on the second rotating element 157, and the second linkage element 158 is slidably disposed on the second active element 156. The second link rod 159 is rotatably disposed on the linkage element 158, and the second link rod 159 is rotatably disposed on the fixing base 155. For brevity, only the first actuating member 151, the first rotating member 152, the first linking member 153, the first link 154, and the fixing base 155 are used as representatives in the following description. Those skilled in the art can understand that the following detailed structures of the first active element 151, the first rotating element 152, the first linkage element 153 and the first link rod 154 may also be applied to the second active element 156, the second rotating element 157, the second linkage element 158 and the second link rod 159.

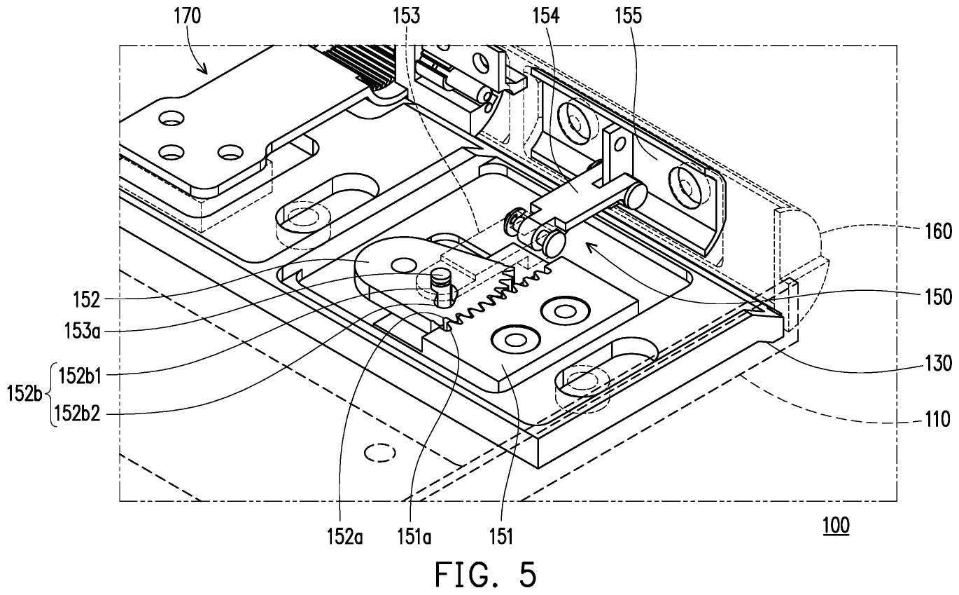

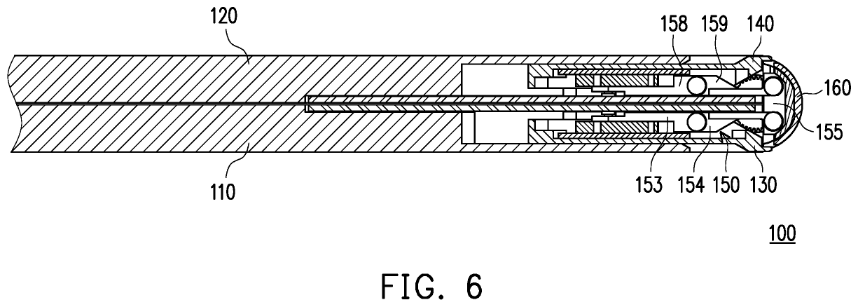

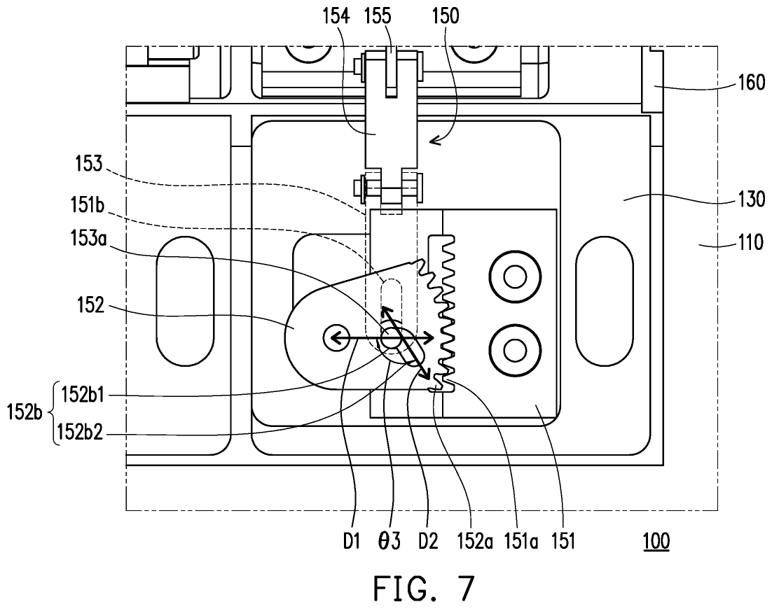

FIG. 5 is a partially enlarged diagram of the foldable electronic device of FIG. 1 from another perspective. FIG. 6 is a partial cross-sectional view of the foldable electronic device of FIG. 5. FIG. 7 is a top view of the foldable electronic device of FIG. 5 with illustration of certain components omitted. For clarity and ease of explanation, certain structures are shown in broken lines in FIG. 5 and FIG. 7 and certain structures are omitted in FIG. 7. Referring to FIG. 4, FIG. 5, FIG. 6 and FIG. 7, the linkage mechanism 150 shown by FIG. 5 is defined as the first state, and the hinge module 170 is connected between the first body 110 and the second body 120. When the linkage mechanism 150 is in the first state, the second body 120 is folded relative to the first body 110. The first active element 151 includes a first groove 151b and a first teeth portion 151a. The second active element 152 includes a second groove 152b and a second teeth portion 152a. The second teeth portion 152a is coupled to the first teeth portion 151a. The first linkage element 153 includes a first shaft 153a. The first shaft 153a is inserted to the first groove 151b and the second groove 152b.

More specifically, the second groove 152b includes a first portion 152b1 and a second portion 152b2 connecting the first portion 152b1. The first portion 152b1 extends along a first direction D1. The second portion 152b2 extends along a second direction D2. A third angle θ3 is included between the first direction D1 and the second direction D2.

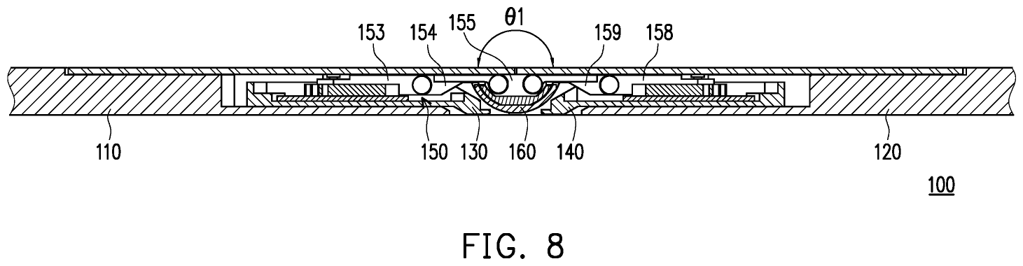

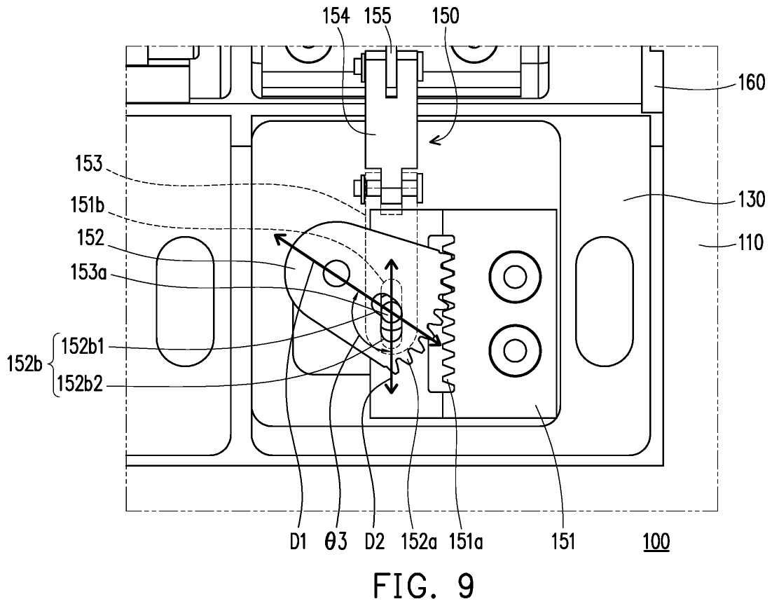

FIG. 8 is a cross-sectional view of the foldable electronic device of FIG. 2. FIG. 9 is a top view of the foldable electronic device of FIG. 2 with illustration of certain components omitted. For clarity and ease of explanation, certain structures are shown in broken lines in FIG. 9 and certain structures are omitted. Referring to FIG. 2, FIG. 5, FIG. 8 and FIG. 9, the linkage mechanism 150 shown by FIG. 2 is defined as the second state. When the linkage mechanism 150 is in the second state, the second body 120 is unfolded to a first angle θ1 relative to the first body 110. The first angle θ1 is, for example but not limited to, 180 degrees.

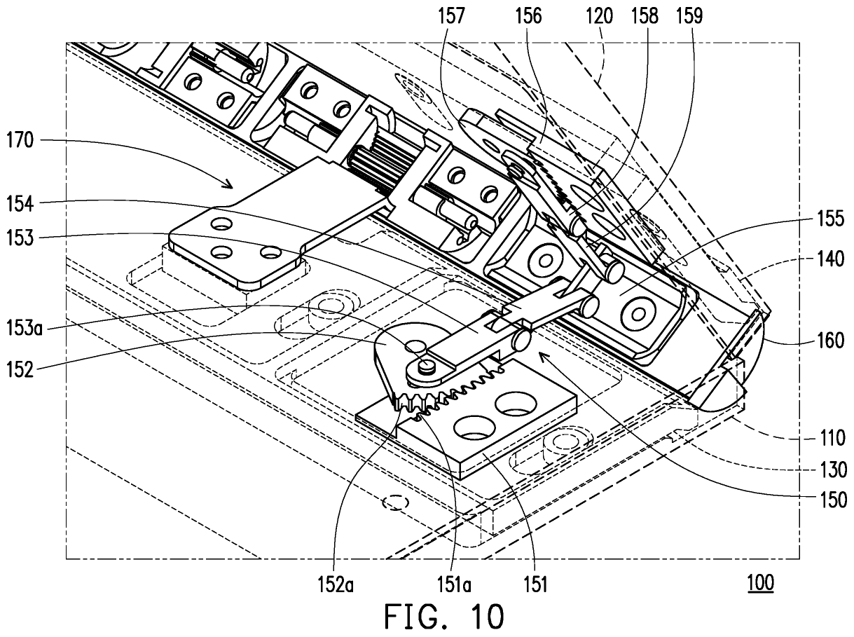

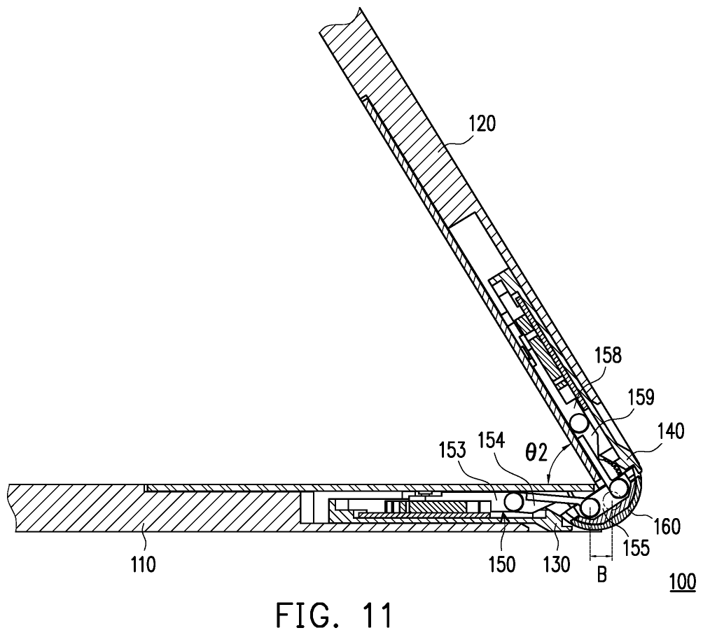

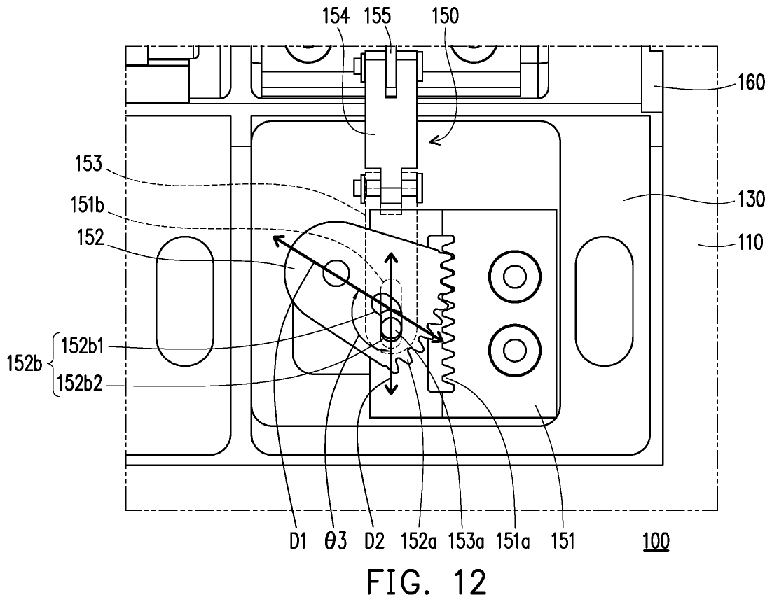

FIG. 10 is a partially enlarged diagram of the foldable electronic device of FIG. 1 unfolded to a second angle from another perspective. FIG. 11 is a cross-sectional view of the foldable electronic device of FIG. 10. FIG. 12 is a top view of the foldable electronic device of FIG. 10 with illustration of certain components omitted. For clarity and ease of explanation, certain structures are shown in broken lines in FIG. 10 and FIG. 12 and certain structures are omitted. Referring to FIG. 5, FIG. 10, FIG. 11 and FIG. 12, the linkage mechanism 150 shown by FIG. 10 is defined as a third state. When the linkage mechanism 150 is in the third state, the second body 120 is unfolded to a second angle θ2 relative to the first body 110. The first angle θ1 is greater than the second angle θ2. The second angle θ2 is, for example but not limited to, 65 degrees. The third angle θ3 is, for example but not limited to, being identical to the second angle θ2. That is to say, the third angle θ3 is, for example but not limited to, 65 degrees.

When the first shaft 153a slides in the first portion 152b1 as shown by FIG. 7 and FIG. 12, the first shaft 153a can drive the first rotating element 152 to rotate on the first body 110, and the active element 151 can slide back and forth. The first active element 151 can further drive the first shielding element 130 to slide on the first body 110. When the linkage mechanism 150 changes from the first state to the third state, the first rotating element 152 rotates by, for example but not limited to, the third angle θ3 Δt this time, a pivotal joint of the first link 154 and the fixing base 155 deflects by a displacement amount B. In this way, this embodiment can achieve the effects of stroke enlargement and control of specific angular displacement.

When the first shaft 153a slides in the second portion 152b2 as shown by FIG. 12 and FIG. 9, only the first shaft 153a slides in the second portion 152b2, and the first rotating element 152, the first active element 151 and the first shielding element 130 are stationary.

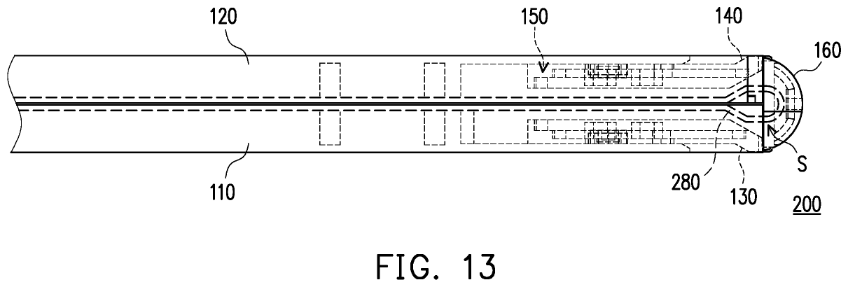

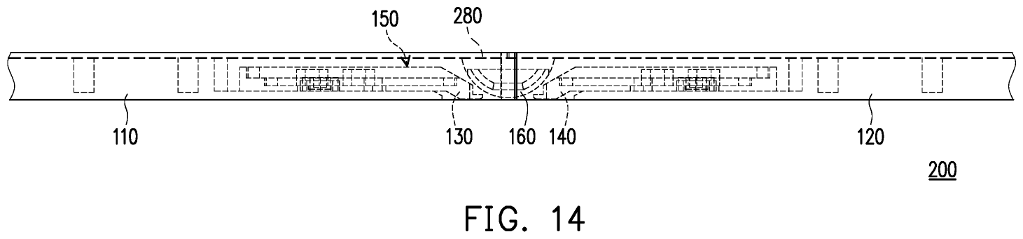

FIG. 13 and FIG. 14 are schematic views of a foldable electronic device in another embodiment of the invention. For clarity and ease of explanation, certain structures are shown in broken lines in FIG. 13 and FIG. 14. Referring to FIG. 13 and FIG. 14, a foldable electronic device 200 includes a flexible display screen 280. The flexible display screen 280 is disposed on the first body 110 and the second body 120. When the second body 120 is folded relative to the first second body 110 as shown by FIG. 13, a portion of the flexible display screen 280 is bent and located in an escape space S. When the second body 120 is unfolded to 180 degrees relative to the first body 110 as shown by FIG. 14, the flexible display screen 280 is flat overall.

In summary, the foldable electronic device of the invention can shield the internal components by the first shielding element, the second shielding element and the cover to achieve beautiful appearance.

Moreover, when the linkage mechanism changes from the first state to the third state, the first rotating element can rotate by the third angle so that the pivotal joint between the first link rod and the fixing base deflects by a displacement amount. In this way, this embodiment can achieve the effects of stroke enlargement and control of specific angular displacement.

Although the present disclosure has been described with reference to the above embodiments, it will be apparent to one of ordinary skill in the art that modifications to the described embodiments may be made without departing from the spirit of the disclosure. Accordingly, the scope of the disclosure will be defined by the attached claims and not by the above detailed descriptions.

1. A foldable electronic device, comprising:
a first body;
a hinge module, pivotally connected to the first body;
a second body, pivotally connected to the hinge module;
a first shielding element, slidably disposed on the first body;
a second shielding element, slidably disposed on the second body; and
a linkage mechanism, disposed on the first body, the first shielding element, the second body and the second shielding element;
wherein the linkage mechanism is changeable between a first state and a second state to drive the first shielding element and the second shielding element to slide, wherein the first shielding element and the second shielding element expose a first area when the linkage mechanism is in the first state, wherein the first shielding element and the second shielding element expose a second area when the linkage mechanism is in the second state, wherein the first area is larger than the second area.

2. The foldable electronic device of claim 1, wherein the second body is folded relative to the first body when the linkage mechanism is in the first state, wherein the second body is unfolded to a first angle relative to the first body when the linkage mechanism is in the second state.

3. The foldable electronic device of claim 2, wherein the linkage mechanism further comprises a third state, wherein the second body is unfolded to a second angle relative to the first body when the linkage mechanism is in the third state, wherein the first angle is greater than the second angle.

4. The foldable electronic device of claim 3, wherein the first angle comprises 180 degrees and the second angle comprises 65 degrees.

5. The foldable electronic device of claim 1, further comprising:
a cover, disposed on the linkage mechanism.

6. The foldable electronic device of claim 5, wherein the linkage mechanism comprises:
a first active element, fixed to the first shielding element;
a first rotating element, rotatably disposed on the first body, and coupled to the first active element;
a first linkage element, movably disposed on the first rotating element, and slidably disposed on the first active element;
a first link rod, rotatably disposed on the first linkage element; and
a fixing base, fixed on the cover, the first link rod being rotatably disposed on the fixing base.

7. The foldable electronic device of claim 6, wherein the active element comprises a first teeth portion, and the first rotating element comprises a second teeth portion coupled to the first teeth portion.

8. The foldable electronic device of claim 6, wherein the first active element comprises a first groove, the first rotating element comprises a second groove, and the first linkage element comprises a first shaft, wherein the first shaft is inserted to the first groove and the second groove.

9. The foldable electronic device of claim 8, wherein the second groove comprises a first portion and a second portion connecting the first portion, wherein the first portion extends along a first direction, and the second portion extends along a second direction, wherein a third angle is included between the first direction and the second direction.

10. The foldable electronic device of claim 9, wherein the first shaft is capable of driving the first rotating element, the first active element and the first shielding element to move when the first shaft slides in the first portion, wherein the first rotating element, the first active element and the first shielding element are stationary when the first shaft slides in the second portion.

11. The foldable electronic device of claim 6, wherein the linkage mechanism further comprises:
a second active element, fixed to the second shielding element;
a second rotating element, rotatably disposed on the second body, and coupled to the second active element;
a second linkage element, movably disposed on the second rotating element, and slidably disposed on the second active element; and
a second link rod, rotatably disposed on the linkage element, the second link rod being rotatably disposed on the fixing base.

12. The foldable electronic device of claim 1, further comprising:
a flexible display screen, disposed on the first body and the second body.
